(19) United States
(12) Patent Application Publication
(10) Pub. No.: US 2019/0036017 A1
(43) Pub. Date: Jan. 31, 2019

(54) MAGNETIC SWITCHING MATERIALS AND PREPARATION THEREOF

(71) Applicants: Mohammad Saghayezhian, Baton Rouge, LA (US); Earl Ward Plummer, Baton Rouge, LA (US); Jiandi Zhang, Baton Rouge, LA (US)

(72) Inventors: Mohammad Saghayezhian, Baton Rouge, LA (US); Earl Ward Plummer, Baton Rouge, LA (US); Jiandi Zhang, Baton Rouge, LA (US)

(73) Assignee: Board of Supervisors of Louisiana State University and Agricultural and Mechanical College, Baton Rouge, LA (US)

(21) Appl. No.: 16/050,091

(22) Filed: Jul. 31, 2018

Related U.S. Application Data
(60) Provisional application No. 62/538,861, filed on Jul. 31, 2017.

(51) Int. Cl. H01L 43/10; H01F 10/12; H01F 41/14; H01L 43/12; H01L 43/02

(52) U.S. Cl. CPC H01L 43/10; H01F 10/126; H01L 43/02; H01L 43/12; H01F 41/14

(57) ABSTRACT

The invention relates to magnetic thin films including a single magnetic layer of La₍₁₋ₓ)SrₓMnO₃ deposited on a non-magnetic substrate. The invention further relates to devices comprising said magnetic thin films and methods of manufacture.

### CROSS-REFERENCE TO RELATED APPLICATIONS

This application claims priority to U.S. Provisional Application No. 62/538,861, filed Jul. 31, 2017, incorporated herein by reference in its entirety.

### STATEMENT REGARDING FEDERALLY SPONSORED RESEARCH OR DEVELOPMENT

This invention was made with government support under Grant No. DE-SC0002136, awarded by the U.S. Department of Energy (DOE). The government has certain rights in the invention.

### BACKGROUND OF THE INVENTION

In electronic industries, it is typically desirous to enhance the functionality of devices while reducing device size and simplifying the fabrication process. Thus, miniaturization of electronic devices with enhanced/new functionality is the ultimate goal in design and fabrication of artificially structured materials. The demand for more energy efficient materials with enhanced functionality requires exploring new and unconventional materials.

The majority of modern electronics are based on integrated circuits etched on silicon and other doped semi-conductors. As the name suggests, this class of materials only take advantage of charge degree of freedom, which limits their functionality. Improved materials utilize the delicate interaction between charge, spin, orbital and lattice degrees of freedom. This connection between different degrees of freedom provides the ability to control one degree of freedom by changing the other. For example, it has been shown that it is possible to control the resistivity (charge) by an external magnetic field (spin). This idea is the foundation of spintronics (Haghiri-Gosnet and Renard, J. Phys. D. Appl. Phys. 2003, 36, R127).

Interfaces between transition metal oxides (TMOs) have proven to be an exquisite platform to discover new phenomena. The delicate interplay between electron, lattice, spin and orbital degrees of freedom often leads to new interfacial phases that are inaccessible in parent materials (Coey, et al., Adv. Phys., 1999, 48, 167; Salamon and Jaime, Rev Mod Phys, 2001, 73; Tokura and Nagaosa, Science, 2000, 288, 462; Borisevich, et al., Phys Rev Lett, 2010, 105, 87204; Martin, et al., Phys. Rev. B, 1996, 53, 14285). This can be largely attributed to the difference in symmetry, lattice mismatch, electronic properties, and magnetic properties between two adjacent materials, as the necessity to maintain interfacial coherency demands a certain level of structural distortion and stoichiometric variance (Borisevich, et al., Phys Rev Lett, 2010, 105, 87204; Zubko, et al., Annu. Rev. Condens. Matter Phys., 2011, 2, 141). Therefore, atomic scale engineering of oxide interfaces is believed to have large potential impact on modern technologies in fields such as nanoelectronics and magnetic memory devices (Kan, et al., Nat. Mater., 2016, 15, 432; Liao, et al., Nature Materials, 2016, 15, 425; Rondinelli and Spaldin, Phys. Rev. B, 2010, 82, 113402; Borisevich, et al., Phys. Rev. Lett., 2010, 105, 227203). The ability to see the structure and composition of an interface on an atomic scale with modern electron microscopy and spectroscopy has been critically important in this field (Yin, et al., Nat. Mater., 2013, 12, 397; Farokhipoor, et al., Nature, 2014, 515, 379).

Progress in magnetic memory devices has benefited greatly from the use of interfacial exchange interactions (Bader, Rev. Mod. Phys., 2006, 78, 1). Phenomena such as exchange bias and exchange spring magnets result from the exchange interactions across interfaces (Nogues and Schuller, J. Magn. Magn. Mater., 1999, 192, 203; Kneller and Hawig, IEEE Trans. Magn., 1991, 27, 3560). A general approach in design is to synthesize two or more magnetically active materials on a non-magnetic substrate, via the formation of nanocomposites, multilayers, self-assembly, etc. (Bader, Rev. Mod. Phys., 2006, 78, 1 ; Zeng, et al., Nature, 2002, 420, 395; Liu, et al., Chem. Soc. Rev., 2014, 43, 8098). In these composite materials, each material has its own magnetic characteristics, and the combination creates modifiable functionalities that are not present in individual components. This philosophy, while proven to be successful, also brings complications in material synthesis because controlled growth of multiple materials is required. This unavoidably requires extra care in the growing process, since different materials can have different optimal thermodynamic growth parameters. An approach that is able to generate magnetic exchange interactions with the synthesis of a single material can be appealing and potentially leads to simplified magnetic structures in designing functional devices.

La_{0.67}Sr_{0.33}MnO₃ (LSMO) is a half-metal soft ferromagnet (FM) with a Curie temperature of 340 K, which is well above room temperature (298 K). The nearly perfect spin-polarization of LSMO and its high Curie temperature, make this material an excellent candidate for spintronic devices (Bowen et al., Appl. Phys. Lett. 2003, 82, 233). The low anisotropy energy of LSMO creates the opportunity to use it as magnetic sensor in magnetoresistive devices (Balcells, et al., Appl. Phys. Lett., 1999, 74, 4014). However, in many existing LSMO devices, in order to achieve the desired functionality, a heterostructure is formed. For example, a previous study demonstrated that, in order to enable exchange bias functionality in LSMO, the material had to be heterostructured with the hard FM SrRuO₃ (Ke, et al., Appl. Phys. Lett. 2004, 84, 5458; Ziese, et al., Appl. Phys. Lett., 2010, 97, 52504). Unfortunately, heterostructures cannot be used efficiently in devices for two reasons: first, the resultant devices function only at low temperature; and second, two or more materials are needed to fabricate the device, thereby complicating the manufacture of such devices.

There remains a need in the art for thin film devices comprising monolithic transition metal oxides, and methods for fabricating such devices. This invention addresses this unmet need.

### SUMMARY OF THE INVENTION

In one aspect of the invention, a magnetic thin film is provided, said magnetic thin film comprising a single, magnetic layer of formula La₍₁₋ₓ)SrₓMnO₃ disposed over a non-magnetic substrate, the single magnetic layer having a bulk phase and an interfacial region that interfaces with the substrate, wherein x is between 0 and 1, and wherein the value of x is larger in the interfacial region than in the bulk phase. In one embodiment, the value of x in the bulk phase is between 0.2 and 0.4. In another embodiment, the value of x in the interfacial region is between 0.4 and 0.6. In one embodiment, the thickness of the single magnetic layer is between 10 unit cells and 50 unit cells. In one embodiment, the thickness of the interfacial region is about 2 unit cells. In one embodiment, the Glaser notation tilt system in the interfacial region is a³¹ a⁻c⁰. In one embodiment, the oxygen octahedral tilt (OOT) of the thin film along [1-10]_{c} is lower in the interfacial region than in the bulk phase. In one embodiment, the out-of-plane lattice constant of the interfacial region is about 3.923 Å. In one embodiment, the substrate is strontium titanate.

In one embodiment, only the interfacial region in the single magnetic layer exhibits antiferromagnetic properties. In another embodiment, the single magnetic layer has exhibits both SMR and IH. In another embodiment, the single magnetic layer exhibits SMR and IH below 340 K. In another embodiment, the single magnetic layer exhibits SMR and IH at room temperature.

In one embodiment, the invention provides a magnetic data storage device comprising the magnetic thin film.

In another aspect of the invention, a method for the manufacture of transition metal oxide devices is provided, including the steps of treating a surface of a non-magnetic substrate to create an atomically flat substrate surface; placing the substrate in a growth chamber; heating the substrate to a deposition temperature in the absence of oxygen; introducing an oxygen/ozone mixture to the growth chamber; and depositing a single transition metal oxide material onto the atomically flat substrate surface to form a single layer material having a bulk phase and an interfacial region that interfaces with the atomically flat substrate surface. In one embodiment, the single transition metal oxide material is deposited using pulsed laser deposition. In another embodiment, the deposition temperature is about 660° C. In another embodiment, the pulsed laser deposition is performed using a laser frequency of about 10 Hz.

### BRIEF DESCRIPTION OF THE DRAWINGS

The following detailed description of preferred embodiments of the invention will be better understood when read in conjunction with the appended drawings. For the purpose of illustrating the invention, there are shown in the drawings embodiments which are presently preferred. It should be understood, however, that the invention is not limited to the precise arrangements and instrumentalities of the embodiments shown in the drawings.

FIG. 1 depicts an exemplary method for the manufacture of transition metal oxide devices.

FIG. 2 is a plot of the RHEED oscillations of 20 uc LSMO/STO (001). The inset shows the RHEED pattern for the substrate before growth and the streak-like pattern after growth.

FIG. 3 depicts the two state switch in 30 uc LSMO at room temperature using different external magnetic fields. The ON state is in the presence of external magnetic field, which is momentary, and the OFF state is in the absence of external magnetic field, which is permanent.

FIG. 4, comprising Elements A and B, depicts the resistivity vs temperature for different thicknesses. All the samples show metallic behavior. Element A is a plot of resistivity versus temperature. Element B is a plot of the change in resistivity versus temperature as a function of temperature.

FIG. 5, comprising Elements A-D, depicts structural characteristics of the thin film-substrate interface. Element A is an STEM-HAADF image of LSMO; the interface is marked with a red arrow. Element B is an STEM-ABF image of LSMO. Element C is a plot of the oxygen octahedral tilt as a function of the distance from the interface. Element D is a plot of the out of plane lattice constant as a function of distance from the interface.

FIG. 6, comprising Elements A and B, depicts lattice characteristics of the inventive materials. Element A depicts the relation between the cubic and orthorhombic lattice vectors of STO and LSMO, respectively. Element B depicts the RLM of 50 uc LSMO/STO (001).

FIG. 7, comprising Elements A-D, depicts structural characteristics of the thin films. Element A depicts the coupled symmetric (θ−2θ) XRD around [002]_{c}; insets show the tilt and rotation of STO and LSMO in the bulk phase. Element B is a plot of the rocking curve about the substrate [002]_{c} peak. Element C is a plot of the rocking curve about the thin film [220]ₒ peak. Elements B and C reveal the absence of texture or mosaicity in the thin film. Element D depicts the RLM around [−103]_{c}.Q_{∥} of substrate and thin film are equal, which shows the thin film is fully strained to the substrate.

FIG. 8 shows various Glaser tilt systems. The data suggest that #20 matches the STEM-ABF image. Yellow circles show the oxygen overlap in #16 and #18; such overlap is absent in #20.

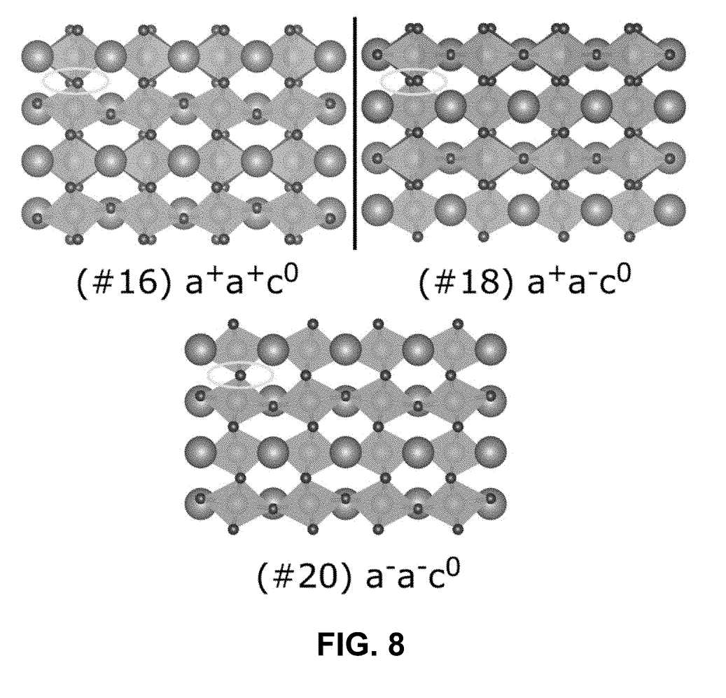

FIG. 9, comprising Elements A and B, depicts structural characteristics of the thin film-substrate interface. Element A shows a plot of the EELS composition profile of La, Mn, Sr, and Ti across the interface, mapped on the structure of the material. Element B shows the La and Sr ratio as a function of layer number from the interface.

FIG. 10 is a plot of the magnetization vs temperature of 50 uc LSMO. The STO antiferro-distortive transition is seen as a kink at 105 K. The inset shows the schematic process for SMR.

FIG. 11 is a plot of the spontaneous magnetic reversal as a function of temperature for different thicknesses.

FIG. 12 is a plot of the effect of various field cooling and warming on magnetization vs temperature of 50 uc of LSMO.

FIG. 13 depicts the AC susceptibility, measured in the presence and absence of a magnetic field. Reentrant FM is observed in below ˜94 K.

FIG. 14 is a plot of the FM hysteresis loop at different temperatures. The open (solid) symbols show leftward (rightward) field sweep, which is shown with an arrow in the legend. The FM hysteresis begins to invert at 75 K.

FIG. 15, comprising Elements A and B, depicts the coercivity characteristics of the thin film. Element A depicts the change in the left and right coercive field as a function of temperature. Element B is a plot of the coercivity and exchange bias as function of temperature.

### DETAILED DESCRIPTION

The invention relates to LSMO thin films deposited on a substrate without a second magnetic material and without a pinning layer. This invention further relates to methods of manufacturing said thin films and devices comprising said thin films.

### Definitions

It is to be understood that the figures and descriptions of the present invention have been simplified to illustrate elements that are relevant for a clear understanding of the present invention, while eliminating, for the purpose of clarity, many other elements found in the art related thin film deposition, spintronic technology, magnetism, and the like. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this invention belongs. Although any methods, materials and components similar or equivalent to those described herein can be used in the practice or testing of the present invention, the preferred methods and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, ±10%, ±5%, ±1%, or ±0.1% from the specified value, as such variations are appropriate.

Throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, 6 and any whole and partial increments therebetween. This applies regardless of the breadth of the range.

Abbreviations: LSMO: lanthanum strontium manganite, La₍₁₋ₓ₎SrₓMnO₃; STO: strontium titanate, SrTiO₃; FM: ferromagnetic; AFM: antiferromagnetic; OOP: out-of-plane; OOT: oxygen octahedral tilt; SMR: spontaneous magnetic reversal; IH: inverted hysteresis.

### Description

The present invention is based, in part, on the unexpected finding that a single soft ferromagnetic material deposited over a non-magnetic substrate can exhibit spontaneous magnetic reversal and inverted hysteresis and can therefore function as an exchange spring magnet.

In another aspect, the present invention provides a method for the manufacture of a monolithic monolayer thin film, deposited on a substrate, that functions as an exchange spring magnet.

### Single Magnetic Layer Thin Films

In one aspect, the invention provides a single layer of a magnetic transition metal oxide thin film, comprising a bulk phase and an interfacial region that interfaces with the substrate. In one embodiment, the interfacial region is understood to be the first 1-2 unit cells of the transition metal oxide thin film on the substrate. In one embodiment, the portion of the transition metal oxide thin film that does not comprise the interface constitutes the bulk phase.

The thin films of the invention are deposited on a non-magnetic substrate. Exemplary non-magnetic substrates are known to those of skill in the art and can include, but are not limited to, polymer substrates formed from polymer materials such as polyethylenes, polyesters, polyolefins, celluloses, vinyl resins, polyimides or polycarbonates, metal substrates formed from aluminum alloys or titanium alloys, ceramic substrates formed from aluminum glass, glass substrates or the like. In one embodiment, the substrate is a perovskite having a formula ABO₃ such as strontium titanate, calcium titanate, lead titanate, bismuth ferrite, lanthanum ytterbium oxide, silicate perovskite, lanthanum manganite, lanthanum aluminate, yttrium aluminum (YAP), and the like. In another embodiment, the substrate can be selected from the group consisting of strontium titanate (STO), strontium ruthenate (SRO), barium titanate (BTO), barium strontium titanate (BST), lead lanthanum titanate (PLT), lead tantalum zirconium (PLZ), strontium bismuth tantalite (SBT), and the like. In one embodiment, the substrate is strontium titanate (STO). In one embodiment, the substrate can be represented by the molecular formula SrTiO₃. In one embodiment, the substrate can include additional dopants that confer desirable properties. Exemplary dopants include niobium, lanthanum, antimony, ruthenium, and the like.

The thickness of the non-magnetic substrate can vary with its physical shape, and therefore is without limitation. For example, for films and sheets, the thickness may be between about 3 and 100 μm, preferably from 5 to 50 μm; for disks and cards, the thickness may range from about 30 μm to 10 mm. The substrates may be in any desirable shape, such as a cylindrical drum shape whose specific configuration is determined by the type of the recorder with which the magnetic recording medium of the present invention is used.

In some embodiments of the invention, the thin film layer thickness can be selected depending on the intended use of the device. In one embodiment, the thin film layer thickness is measured in unit cells (uc). In one embodiment, one unit cell equals approximately 0.3846 nm. In one embodiment, the thin film layer thickness, measured as the depth of the layer relative to the surface of the substrate, is greater than about 10 uc. In one embodiment, the thickness is about 10 uc. In one embodiment, the thin film thickness is about 20 uc. In one embodiment, the thin film thickness is about 30 uc. In one embodiment, the thin film thickness is about 40 uc. In one embodiment, the thin film thickness is about 50 uc. In one embodiment, the thin film thickness is between 10 uc and 50 uc. In one embodiment, the thin film thickness is greater than about 50 uc.

In one embodiment, the magnetic transition metal oxide is a lanthanum strontium manganite (LSMO), but the invention is not limited thereto. In one embodiment, the transition metal oxide is any doped or non-doped magnetic perovskite material known to those of skill in the art that has a different symmetry, tilt, and rotation system when grown epitaxialy over a perovskite substrate when compared to that of the bulk material. In one embodiment, the transition metal oxide can be represented by the formula La₍₁₋ₓ₎SrₓMnO_{y}, wherein x is between 0 and 1, and y is an integer selected from 3 and 4. In one embodiment, the value of x in the bulk phase is between about 0.20 and about 0.50. In one embodiment, the value of x in the bulk phase is about 0.33. In some embodiments of the invention, x has a different value in the interfacial region than in the bulk phase. In one embodiment, the value of x is larger in the interfacial region than in the bulk phase. In one embodiment, the value of x in the interfacial region is greater than or equal to about 0.5. In one embodiment, the value of x in the interfacial region is greater than or equal to about 0.6. In one embodiment, the value of x in the interfacial region is between about 0.4 and about 0.75. In one embodiment, the value of x in the interfacial region is about 0.6. In one embodiment, the value of x in the interfacial region is about 0.48. In one embodiment, the value of y is lower in the interfacial region than in the bulk phase.

In one embodiment, the thin film is highly crystalline. In one embodiment, the thin film is fully strained with respect to the substrate. In one embodiment, the epitaxial and coherent thin film exhibits corner-shared octahedra connected at the interface, which may result in structural modification compared to the substrate bulk material and the thin film transition metal oxide bulk material. In one embodiment, the oxygen octahedral tilt (OOT) of the thin film along [1-10]_{c} is different in the interfacial region compared to the bulk phase. In one embodiment, the average OOT in the interfacial region increases as a function of distance from the interface. In one embodiment, the OOT in the interfacial region is lower than that of the bulk phase. In one embodiment, the average OOT in the interfacial region is between 3.0° and 7.0°. In one embodiment, the average OOT in the interfacial region is between 3.8° and 6.3°. In one embodiment the average OOT in the first unit cell of the thin film layer is about 4.5°±0.7°. In one embodiment, the average OOT in the second unit cell of the thin film layer is about 5.6°±0.7°. In one embodiment, the average OOT in the bulk phase is lower than that of the bulk material. In one embodiment, the average OOT in the bulk phase is lower than about 6.8°. In one embodiment, the average OOT in the bulk phase is between about 5.0° and about 6.8°. In one embodiment, the average OOT in the bulk phase is about 6.1°±0.7°. In one embodiment, the tilt and rotation system for LSMO/STO (001) in the [1-10]_{c} 00 direction is a⁻a⁻c⁰ (#20) according to Glaser's notation.

In one embodiment, tensile strain originating from the lattice mismatch with the substrate material effects a difference in the out-of-plane (OOP) lattice constant of the thin film material with respect to the bulk material. In one embodiment, the OOP lattice constant of the thin film layer is greater in the interfacial region than in the bulk phase. In one embodiment, the OOP lattice constant of the interfacial region is between about 3.800 Å and about 4.000 Å. In one embodiment, the OOP lattice constant of the interfacial region is about 3.923±0.056 Å.

In one embodiment, the corner-shared octahedra of the thin film are connected at the interface. In one embodiment, the octahedra of the thin film layer are distorted with respect to that of the bulk material. In one embodiment, the OOP lattice constant of the thin film layer bulk phase is between about 3.840 Å and about 3.880 Å. In one embodiment, the OOP lattice constant of the thin film layer is about 3.848 Å. In one embodiment, the OOP lattice constant of the thin film transition metal oxide is lower than that of the bulk crystal. In one embodiment, the OOP lattice constant of the substrate is the same as that of the bulk material.

In one embodiment, the OOT angle of the thin film induces an OOT in the substrate. In one embodiment, the average OOT of the substrate decreases as a function of distance from the interface. In one embodiment, the average OOT of the first unit cell of the substrate is greater than 0.0°. In one embodiment, the substrate exhibits an ideal cubic perovskite structure beyond the first 5 unit cells from the interface. In one embodiment, the substrate exhibits a⁰a⁰a⁰ symmetry according to Glaser's notation beyond the first 5 unit cells from the interface.

In one embodiment of the invention, the single layer thin film may be cooled from about 380 K to about 2 K under a magnetic field of about 1000 Oe. In one embodiment, the single layer thin film exhibits a spontaneous magnetic reversal (SMR) in the negative direction at a temperature between 50 K and 150 K when warmed from 2 K under zero field warming (ZFW) conditions. In one embodiment, the SMR occurs at a temperature between 50 K and 100 K. In one embodiment, the SMR occurs at a temperature between 75 K and 125 K. In one embodiment, the SMR occurs at a temperature between 60 K and 75 K. In one embodiment, the single layer thin film exhibits SMR in thin films of thickness between 10 uc and 50 uc. In one embodiment, the temperature at which SMR is tuned via film thickness. For example, in one embodiment, the SMR occurs at about 75 K for a thin film layer of about 50 uc. In one embodiment, no SMR is observed when a moderate magnetic field of between 15 Oe and 50 Oe is applied during warming.

In one embodiment, the single layer thin film comprises an antiferromagnetic (AFM) region and a ferromagnetic (FM) region. In one embodiment, the antiferromagnetic region of the single layer thin film is the interfacial region. In one embodiment, the ferromagnetic region of the single layer thin film is the bulk phase. In one embodiment, this result is in direct contrast to previous works, wherein a heterostructure of multiple layers, comprising more than one bulk material, is necessary to create a system capable of SMR. In one embodiment, the interface-driven AFM interaction in the interfacial region controls the magnetization of the entire single layer thin film. In one embodiment, the magnetic susceptibility of the single layer thin film is dependent on the strength of the applied magnetic field.

In one embodiment of the invention, the single layer thin film cooled from about 380 K to about 2 K under a magnetic field of about 1000 Oe, then warmed under ZFW conditions, exhibits inverted hysteresis (IH). In one embodiment, inverted hysteresis describes a scenario wherein the magnetization of the single layer thin film is negative in the presence of a positive magnetic field. In one embodiment of the invention, the magnetization of the single layer thin film is negative when a positive external magnetic field is applied. In another embodiment of the invention, the magnetization of the single layer thin film is positive when a negative external magnetic field is applied. In one embodiment of the invention, the presence of IH behavior indicates that the single layer thin film exhibits negative coercivity. In one embodiment, the single layer thin film exhibits IH at a temperature between 50 K and 100 K. In one embodiment, the single layer thin film exhibits IH at a temperature greater than about 75 K. In one embodiment, the degree of negative coercivity in the single layer thin film increases with increasing temperature. In one embodiment, the negative coercivity of the single layer thin film increases over increasing temperatures between about 100 K and about 275 K. In one embodiment, the negative field coercivity saturates at about 275 K. In one embodiment, the single layer thin film exhibits IH at a temperature between 75 K and 325 K. In one embodiment, the single layer thin film exhibits IH at room temperature. In one embodiment, the single layer thin film exhibits IH at temperatures greater than or equal to room temperature. In one embodiment, the single layer thin film exhibits an exchange bias at temperatures between 75 K and 325 K.

In one embodiment, the single layer thin film exhibits SMR and IH. In one embodiment of the invention, SMR and IH are observed in a single layer thin film made from a single magnetic bulk material. In one embodiment, the SMR and IH properties may be attributed to the AFM behavior of the interfacial region of the single layer thin film. In one embodiment, the single layer thin film does not require a separate pinning layer comprising a second magnetic bulk material to act as an antiferromagnetic layer. In one embodiment, the lack of a pinning layer allows for much thinner thin films for application in spintronic devices.

In one embodiment, the single layer thin film can act as a two-state switch upon application and subsequent removal of a magnetic field. In one embodiment, in the absence of magnetic field, the bulk phase naturally aligns anti-parallel with the interfacial region, which exhibits a negative magnetization. In another embodiment, the application of an external positive magnetic field with a Zeeman energy larger than the AFM exchange coupling energy results causes the bulk phase to align parallel to the external magnetic field and the interfacial region. In one embodiment, the removal of the external magnetic field causes the bulk phase to reassume the anti-parallel alignment (negative magnetization). In one embodiment, the switchable magnetic states are controlled by presence/absence of an external magnetic field. In one embodiment, the switchable magnetic states of the single layer thin film are observed upon application of an external magnetic field of between 10 Oe and 1000 Oe. In one embodiment, the switchable magnetic states are observed upon application of an external magnetic field of about 10 Oe. In one embodiment, the switchable magnetic states are observed upon application of an external magnetic field of about 20 Oe. In one embodiment, the switchable magnetic states are observed upon application of an external magnetic field of about 50 Oe. In one embodiment, the switchable magnetic states are observed upon application of an external magnetic field of about 1000 Oe.

### Methods of the Invention

In one aspect, the invention provides a method of depositing a thin film transition metal oxide on a substrate.

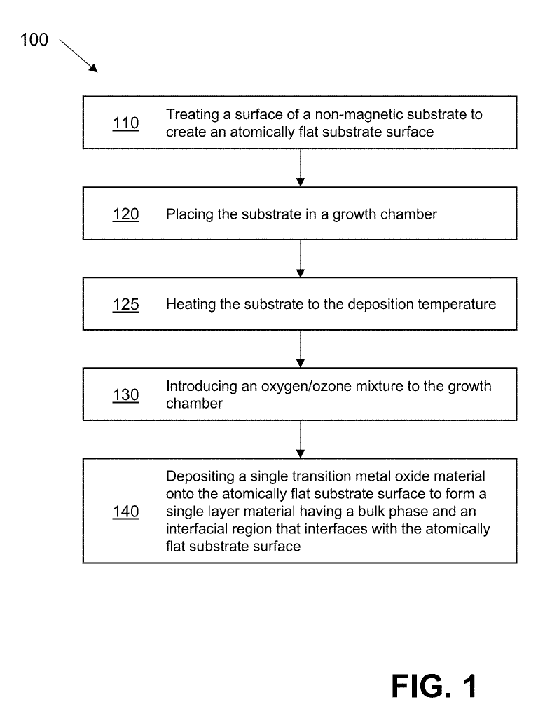

Exemplary method 100 is shown in FIG. 1. The method begins with exemplary step 110, wherein the surface of a non-magnetic substrate is treated to create an atomically flat substrate surface. In exemplary step 120, the substrate is placed in a growth chamber. The substrate is then heated to the deposition temperature as shown in exemplary step 125. In exemplary step 130, an oxygen/ozone mixture is introduced into the growth chamber. Finally, in exemplary step 140, a single transition metal oxide material is deposited onto the atomically flat substrate to form a single layer material having a bulk phase and an interfacial region that interfaces with the atomically flat substrate surface.

In one embodiment, the target substrate surface is prepared prior to deposition. For example, it may be beneficial to create an atomically flat surface using techniques known to those in the art. In one embodiment, the substrate is soaked in acetone for five minutes, then in ethyl alcohol for five minutes, and finally in electronics-grade DI water; the three soakings may be performed under sonication. In one embodiment, the substrate is submerged in hydrofluoric acid (HF) for 30 seconds and then dipped in DI water to remove residual HF. In one embodiment, the substrate is annealed by any method known in the art, such as by placement in an 0.2 MPa oxygen atmosphere for about 150 min at about 1215 K.

In some embodiments, the target surface (substrate) is heated under vacuum to the deposition temperature prior to deposition. In one embodiment, the deposition temperature is greater than about 500° C. In one embodiment, the deposition temperature is between about 500 and about 1000° C. In one embodiment, deposition temperature is between about 500 and about 750° C. In one embodiment, the deposition temperature is between about 600 and about 700° C. In one embodiment, the to deposition temperature is about 660° C. In some embodiments, the pressure and temperature surrounding the target surface changes during deposition.

In one embodiment, the substrate surface is heated gradually until the deposition temperature is reached. In one embodiment, the substrate is heated to the desired temperature over a course of between 1 minute and 60 minutes. In one embodiment, the substrate is heated to the desired temperature over a course of between 1 minute and 30 minutes. In one embodiment, the substrate is heated to the desired temperature over a course of between 1 minute and 15 minutes. In one embodiment, the substrate is heated to the desired temperature over about 12 minutes.

In one embodiment, the thin film deposition takes place in a vacuum. In one embodiment, the deposition takes place at low pressure. In one embodiment, the deposition takes place under an atmosphere of oxygen, ozone, or a combination thereof. In one embodiment, the deposition takes place at a pressure of less than 100 mTorr. In one embodiment, the deposition takes place at 80 mTorr.

In some embodiments, the single transition metal oxide is deposited using methods known to those of skill in the art, such as chemical deposition techniques including chemical vapor deposition (CVD), chemical solution deposition, electroplating, dip coating, plasma-enhanced CVD, laser-induced CVD, and atomic layer deposition; physical deposition techniques such as physical vapor deposition (PVD), pulsed laser deposition (PLD), cathodic arc deposition, molecular beam epitaxy, electron beam PVD, and sputter deposition; or layer-by-layer growth. In some embodiments, thin film deposition proceeds via epitaxial growth. Exemplary methods for epitaxial growth include, but are not limited to, molecular beam epitaxy, chemical vapor deposition, and pulsed laser deposition. In one embodiment, the thin film is deposited using pulsed laser deposition.

In some embodiments of the invention, precise control of the deposition parameters can modulate the functionalities of the resulting thin films. In one embodiment, pulsed laser deposition parameters include wavelength, target material, fluence (energy/unit area), vacuum conditions, presence/pressure of an ambient gas, be it inert or reactive, angle of incidence of laser beam relative to the substrate surface, and substrate temperature. In one embodiment, the substrate is strontium titanate (STO).

In one embodiment, the laser energy (fluence) is between 1 and 3 J/cm². In one embodiment, the laser energy is between 1 and 1.5 J/cm². In one embodiment, the laser energy is about 1.5 J/cm². In one embodiment, the laser energy is about 2 J/cm² In one embodiment, the laser repetition rate is between 7 and 10 Hz. In one embodiment, the laser repetition rate is about 10 Hz. In one embodiment, the lateral dimensions of the laser are about 0.5×1 mm².

In some embodiments, the thin film deposition starts immediately after introduction of oxygen, such as after less than about one minute. In one embodiment, the thin film deposition proceeds quickly. In one embodiment, the properties of the thin film may be modulated by controlling time intervals in the exemplary protocol shown in FIG. 1, such as the rate of substrate heating, the interval between the attainment of the deposition temperature and the introduction of oxygen, and the interval between the introducing of oxygen and the start of deposition. In some embodiments, it may be useful to monitor the growth of the thin film on the target substrate using a method known to those of skill in the art, such as reflection high energy electron diffraction (RHEED).

It should be appreciated that the acid etching (HF treatment) of the substrate removes the top layer of SrO from the SrTiO₃ substrate. Heating the substrate in the absence of oxygen, such as under a high vacuum of about 10⁻⁸ Torr, minimizes the amount of SrO on the surface of the substrate. In one embodiment, the substrate is heated rapidly, such as from room temperature to the desired deposition temperature over about 12 minutes. Without wishing to be bound by any particular theory, it is possible that rapid substrate warming prevents the formation of oxygen vacancies and/or the formation of higher oxidation state transition metal oxides in the substrate. Adding oxygen and then immediately starting deposition maintains the atomic structure of the substrate surface while preventing oxygen vacancies in the deposited material. Rapid deposition, such as can be attained using pulsed laser deposition and a laser frequency of between 7 and 10 Hz, further maintains the desired substrate surface composition.

### Devices of the Invention

In one aspect, the invention includes devices comprising any of the single layer thin film transition metal oxides deposited on a substrate as described herein. In one embodiment, the single layer thin film is incorporated into a device known to those in the art. In one embodiment, such devices include any system that is sensitive to the direction of magnetization. Exemplary devices include, but are not limited to, magnetic field sensors, data storage units, magnetic random access memory (MRAM) digital storage devices, spin valves, and solid-state digital storage units. In one embodiment, the single layer thin film is incorporated into a data storage unit. In one embodiment, the single layer thin film is used in a magnetic random access memory (MRAM) digital storage device.

### EXPERIMENTAL EXAMPLES

The invention is further described in detail by reference to the following experimental examples. These examples are provided for purposes of illustration only, and are not intended to be limiting unless otherwise specified. Thus, the invention should in no way be construed as being limited to the following examples, but rather, should be construed to encompass any and all variations which become evident as a result of the teaching provided herein.

Without further description, it is believed that one of ordinary skill in the art can, using the preceding description and the following illustrative examples, make and utilize the thin films of the present invention and practice the claimed methods. The following working examples therefore, specifically point out the preferred embodiments of the present invention, and are not to be construed as limiting in any way the remainder of the disclosure.

### Example 1

### Room Temperature Momentary Exchange Spring Magnetic Switching in Complex Oxide Thin Films

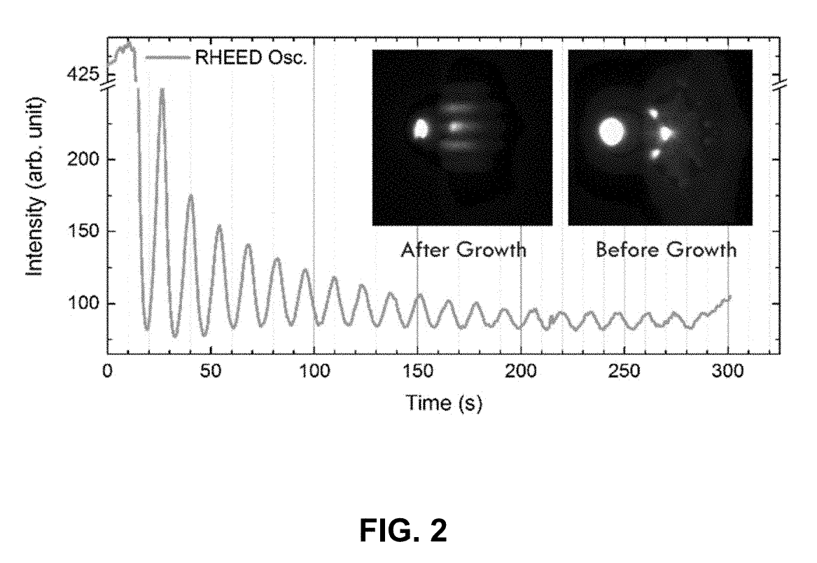

As demonstrated herein, thin films of La_{0.67}Sr_{0.33}MnO₃/SrTiO₃ (001) were grown using pulsed laser deposition. Prior to growth, the substrates were treated ex-situ to create an atomically flat TiO2 terminated substrate. The substrate was first cleaned in sonicated acetone, then ethyl alcohol, each for five minutes, followed by sonication in electronics grade DI-water for 4 minutes. After that, it is submerged in HF acid for 30 seconds and dipped in DI-water to remove any HF residual. Finally, the substrate is annealed in 0.2 MPa 99.999% oxygen for 150 min at 1215 K (Temperatures are subject to 10 K error). The growth temperature and oxygen pressure were 660° C. and 80 mTorr. The laser energy was adjusted to 1.5 J/cm² with repetition rate of 10 Hz with lateral dimensions of 0.5×1 mm². The substrate temperature was gradually increased to the growth temperature in the absence of oxygen, then an oxygen/ozone mixture was introduced in the vacuum chamber. This step removes any unwanted contamination from the surface. After oxygen/ozone introduction, the growth was started immediately. This step was done as quickly as possible to produce the desired switching properties. The growth dynamic was monitored in real-time using reflection high energy electron diffraction (RHEED) to ensure epitaxial growth. FIG. 2 shows the RHEED oscillations for a 20 unit cell (uc) thin film; the inset shows the RHEED pattern of substrate before the growth. The presence of Kikuchi lines demonstrates the quality of the substrate. After the growth, the streak-like RHEED pattern reveals the quasi 2D nature of the thin film.

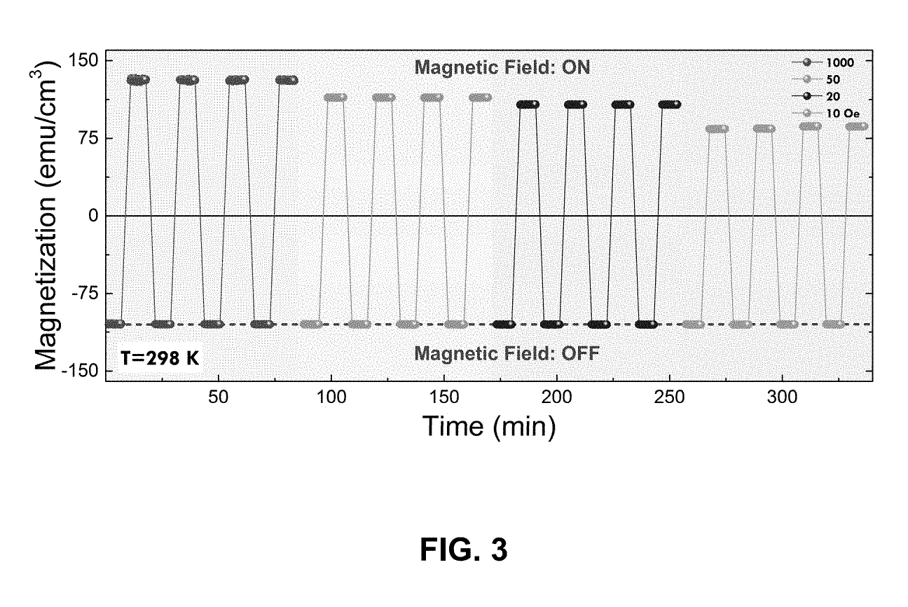

After the growth, the sample was cooled down at growth pressure. The structure and composition of thin films were studied by X-ray diffraction (XRD) and transmission electron microscopy (TEM), which both methods proved the high quality of the thin films on macroscopic and microscopic level. The electronic transport shows that all the thin films exhibit metallic behavior below Curie temperature. The magnetic properties measurements were performed using a superconducting quantum interference device (SQUID) where the switching behavior was observed. FIG. 3 shows the change in the magnetization of this material. The magnetization lies in the plane of thin film and the external magnetic field was applied in this direction.

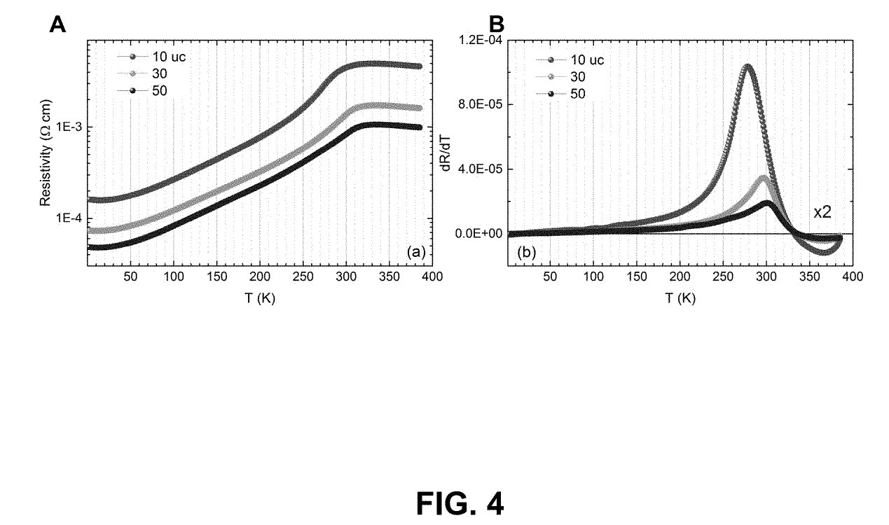

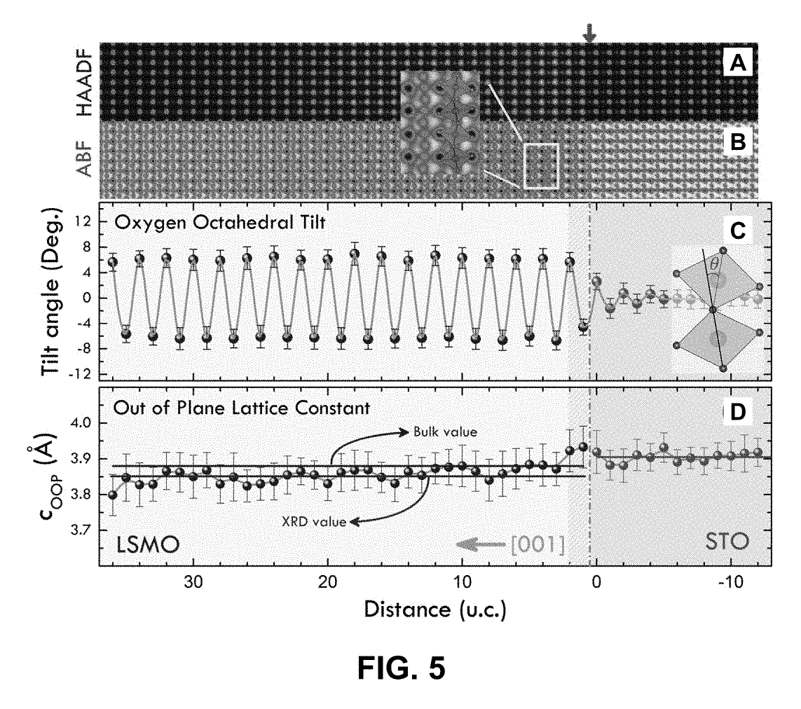

FIG. 4 shows the electrical transport properties of the thin films. The thin films demonstrate metallic behavior down to 2 K without any sign of localization upturn at very low temperature. FIG. 5 Element B shows the derivative of resistivity with respect to temperature. The insulator-to-metal transition temperature (based on change in slop sign) for different thicknesses is very close, 333, 336 and 337 K for 10, 30 and 50 unit cells, respectively.

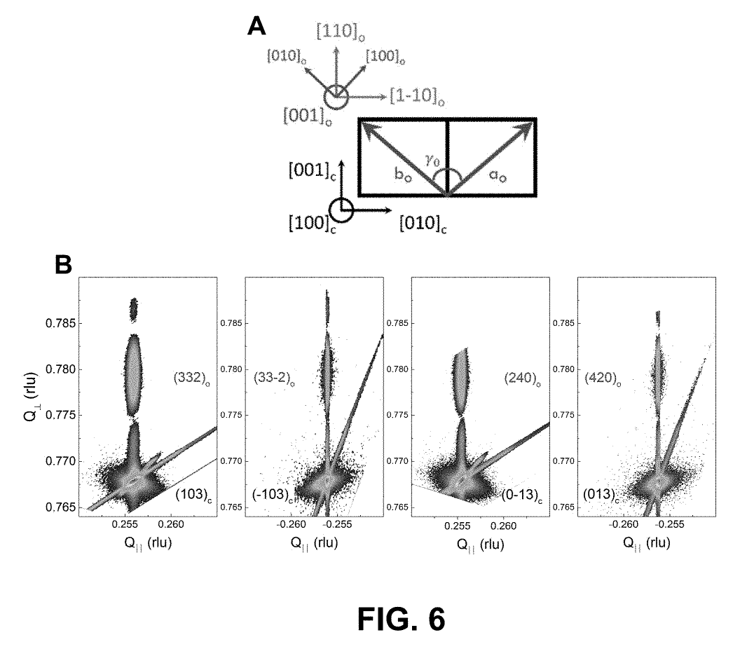

Reciprocal Lattice Mapping (RLM) shows that the LSMO thin film has orthorhombic symmetry. The Miller indices of cubic and orthorhombic (FIG. 6) are related by the following equations.

$${h}_{o} = {( k + l )}_{c} {k}_{o} = {( k - l )}_{c} {l}_{o} = 2 {h}_{c}$$

$$\frac{1}{{d}_{hkl}^{2}} = \frac{{h}^{2}}{{a}_{c}^{2}} + \frac{{k}^{2}}{{b}_{c}^{2}} + \frac{{l}^{2}}{{c}_{c}^{2}}$$

$${a}_{o} = \sqrt{{b}_{c}^{2} + {c}_{c}^{2}} , \vec{{a}_{o}} + \vec{{b}_{o}} = 2 {c}_{c} = \sqrt{{a}_{o}^{2} + {b}_{o}^{2} - 2 {a}_{o} {b}_{o} cos {γ}_{o}}$$

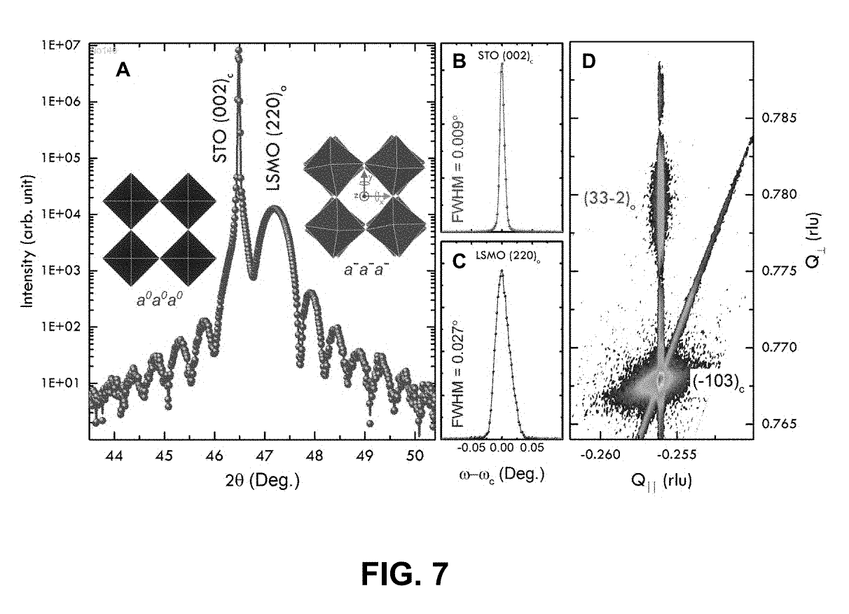

In the bulk phase, LSMO has a rhombohedral structure and STO exhibits an ideal cubic perovskite structure. In Glazer's notation (Glazer, Acta Crystallogr. Sect. B Struct. Crystallogr. Cryst. Chem., 1972, 28, 3384), bulk LSMO crystal shows an “a⁻a⁻a⁻” symmetry where the octahedra rotate, equally and out-of-phase, around each pseudocubic axis (FIG. 7) (Vailionis, et al. Phys. Rev. B-Condens. Matter Mater. Phys., 2011. 83, 64101). STO does not show any rotation or tilt, i.e. “a⁰a⁰a⁰. ” In order to determine the LSMO structure in epitaxial thin film, X-ray diffraction (XRD) measurement of a 50 uc LSMO/STO (001) thin film was performed and data are shown in FIG. 7 Element A. The presence of Fresnel oscillations confirms the smoothness of the surface and interface as well as the high quality of the thin film on a macroscopic level. The out-of-plane (OOP) lattice constant is 3.848±0.003 Å. This value is smaller than bulk lattice constant, 3.876 Å (Martin, et al., Phys. Rev. B, 1996, 53, 14285), due to tensile strain originating from the lattice mismatch with STO (a_{STO=}3.904 Å). FIG. 7 Elements B and C show the rocking curve measurements around the substrate and thin film peaks. The full width at half maximum (FWHM) of two the peaks are comparable, which confirms the high crystallinity of the thin film. FIG. 7 Element D shows the reciprocal lattice mapping (RLM) around [−103]_{c}, showing that the thin film is fully strained and coherently follows the substrate. In order to further study the structural parameters of LSMO thin film on STO, RLM around asymmetric reflections were measured at room temperature. FIG. 6 shows the RLMs of LSMO/STO (001) under tensile strain around (332), (33-2), (240) and (420) reflections in orthorhombic notation. (332) and (240) reflections are broader than (33-2) and (420) reflections which is due to a geometric effect from the absence of crystal analyzer on the detector side of X-ray diffractometer. The vertical (Q_{∥}) alignment of substrate and layer reflections shows that the thin film is fully strained with respect to the substrate. This condition will strongly suppress the rotation of octahedral around [001]_{c}. The RLMs show that aₒ and bₒ are equal and therefore, a_{c}=b_{c}>c_{c}. Using reflection positions, a_{c}=b_{c}=3.899±0.005 Å, which means aₒ=bₒ=\sqrt{a_{c}²+c_{c}²}=5.476±0.007 Å with γₒ=90.72°. According to Glazer's notation, these lattice parameters belong to “a⁻a⁺c⁰” (#18) or “a⁺a⁺c⁰” (#16), where the rotation of octahedral around [001]_{c} is suppressed, while the tilt around [010]_{c} and [100]_{c} is preserved. It should be noted that Glazer's systems are generated under the assumption that the octahedral remains rigid, however, according to Woodward (Woodward, Acta Crystallogr. Sect. B Struct. Sci., 1997, 53, 32), in order to preserve the connectivity of the octahedral under “a⁻a⁺c⁰” tilt system, the octahedra should deform. The deformations, i.e. change in bond length or angle, are very small and are not accessible to XRD (Vailionis, et al. Phys. Rev. B—Condens. Matter Mater. Phys., 2011. 83, 64101). The RLM data show that the thin film is strained uniformly and is similar to previous reports (Vailionis, et al. Phys. Rev. B—Condens. Matter Mater. Phys., 2011. 83, 64101; Vailionis, et al., Appl. Phys. Lett., 2014, 105, 131906; Boschker, et al., J. Phys. D. Appl. Phys., 2011, 44, 205001).

The tilt and rotation of the thin films was determined by complementary use of atomic resolved scanning transmission electron microscopy (STEM) and XRD. RLM around (332)ₒ, (33-2)ₒ, (240)ₒ and (420)ₒ Bragg peaks shows in-plane lattice constants are equal, a_{c}=b_{c}, and that they are larger than the out-of-plane lattice constant c_{c}, which is expected because the thin film is under tensile strain on a cubic substrate. In Glazer's notation, which assumes the octahedral remains rigid, this structure matches a⁻a⁻c⁰ (#20), a⁺a⁻c⁰ (#18) and a⁺a⁺c⁰ (#16) tilt and rotation systems. In a previous XRD study (Vailionis, et al., Phys. Rev. B-Condens. Matter Mater. Phys., 2011, 83, 64101), a⁺a c⁰ was identified as the tilt and rotation system for LSMO/STO (001). Here, using STEM, it was shown that #20 is the correct tilt and rotation system.

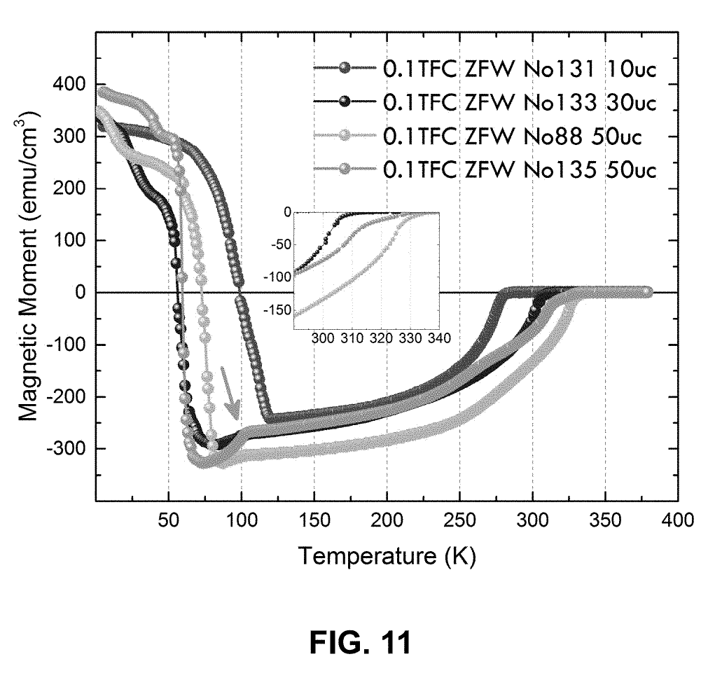

In order to have an epitaxial and coherent thin film, the corner-shared octahedra should be connected at the interface and structural modification is expected. Atomic resolved scanning transmission electron microscopy (STEM) was used to examine the symmetry mismatch at the interface. Using both high angle annular dark field (HAADF), which is sensitive to heavier elements, and annular bright field (ABF) imaging that is more sensitive to light elements such as oxygen, the octahedral tilt was determined. The images were acquired along [1-10]_{c} since the atomic arrangement in other directions such as [100]_{c} or [110]_{c} cannot resolve the tilt structure (Li, et al., Sci. Rep., 2017, 7, 40068). The STEM-HAADF and STEM-ABF images of LSMO/STO (001) are shown in FIG. 5, Elements A and B, respectively. The interface is abrupt, well-ordered and marked by a red arrow. The STEM-ABF image (FIG. 5, Element B) shows zig-zag pattern of oxygen atoms which is visible from the interface to the surface. The oxygen octahedral tilt (OOT) as function of distance from interface is shown in FIG. 5, Element C. The first few unit cells of STO show a decaying OOT into the bulk, where STO recovers its a⁰a⁰a⁰ tilt system. A similar distortion is seen in the first two unit cells of LSMO (shaded in yellow), showing suppressed OOT angles of average value 4.5°±0.7° and 5.6°±0.7°, respectively. After the third unit cell, LSMO exhibits an OOT value of 6.1°±0.7°, close to the bulk value 6.8° (Hwang, et al., Phys. Rev. Lett., 1995, 75, 914). Going across the interface, the transition from octahedral tilted LSMO to non-tilt STO cannot be abrupt. To preserve corner-connectivity, the OOT angle decreases in LSMO and OOT is induced in the non-tilt STO substrate, a result similar to previous reports in other systems (Liao, et al., Nature Materials, 2016, 15, 425; Kim, et al., Adv. Mater., 2013, 25, 2497). Looking at the #16 and #18 tilt systems in the [1-10]_{c} direction and comparing it to the ABF image, neither #16 nor #18 can be the correct tilt system (FIG. 11). On the other hand, #20 matches the ABF image, and therefore is the correct tilt system. FIG. 5 Element D shows the out-of-plane (OOP) lattice constant as a function of the distance from the interface. The blue and red solid lines show the bulk lattice constants of LSMO and STO, respectively. Within experimental error, the STO lattice constant displays the bulk value, while LSMO shows a peculiar behavior near the interface. The first two unit cells near the interface, shaded in yellow, show an unusual elongation, 3.923±0.056 Å and 3.922±0.056 Å, respectively, compared to the bulk value of 3.876 A (Martin, et al., Phys. Rev. B, 1996, 53, 14285). Similar behavior has recently been reported (Li, et al., Sci. Rep., 2017, 7, 40068; Vailionis, et al., Appl. Phys. Lett., 2014, 105, 131906). Away from the interface, the OOP lattice constant restores to a smaller value, which agrees with the XRD measurements.

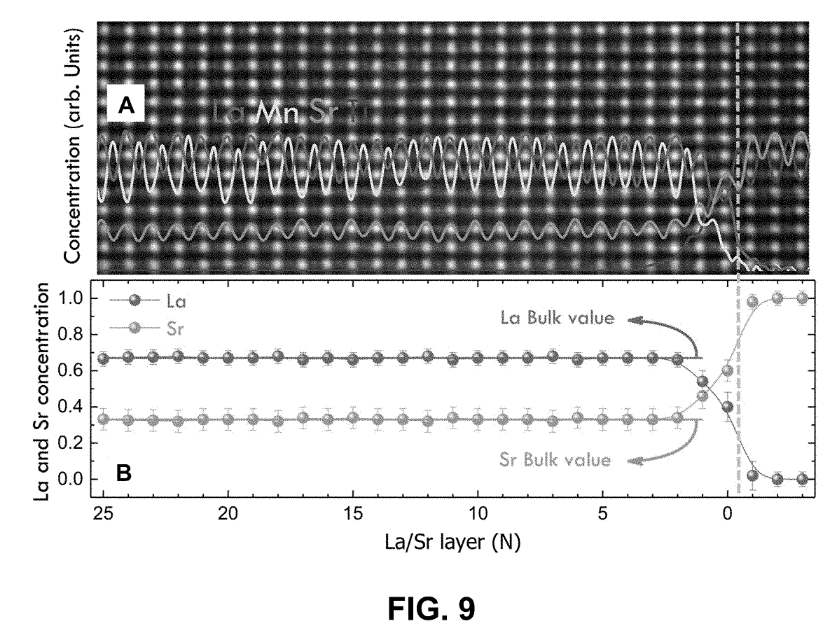

The stoichiometric variation near the interface, and the concentration of each element, is measured using atomic resolved electron energy loss spectroscopy (STEM-EELS). FIG. 9 Element A shows the atomical resolved La, Mn, Sr, and Ti concentration, and FIG. 9 Element B shows the Sr and La concentrations for each layer. In the first and second row, which constitutes one unit cell, the concentrations are La_{0.4}Sr_{0.6} and La_{0.52}Sr_{0.48}, respectively. From the third row, which is the second unit cell, the concentration recovers its bulk value, i.e. La_{0.67}Sr_{0.33}.

The STEM data illustrate subtle changes in both structure and stoichiometry within a unit cell of the interface. The OOP lattice constant, OOT angle and LaSr concentration show continuous change across the LSMO/STO interface to maintain the interfacial coherency and octahedral connectivity (Guo, et al., Proc. Natl. Acad. Sci., 2017, 201706814). In the bulk, increased Sr concentration favors a smaller OOP LSMO lattice constant, however, in our sample, the first two unit cells, where Sr concentration is higher, show a larger lattice constant (Urushibara, Y. Moritomo, T. Arima, A. Asamitsu, G. Kido, and Y. Tokura, Phys. Rev. B, 1995, 51, 14103). This behavior can be ascribed to the very different tilt patterns of LSMO and STO: the rigidity of octahedral in STO with its larger lattice constant is inducing elongation of the OOP lattice constant in LSMO to maintain the octahedral connectivity. It is significant that the first unit cell has a variant composition of (La_{0.4}Sr_{0.6})_{0.5}(La_{0.55}Sr_{0.45})_{0.5}MnO₃, and according to the bulk phase diagram, it should exhibit AFM coupling (Hemberger, et al., Phys. Rev. B, 2002, 66, 94410; Dagotto, et al., Phys. Rep., 2001, 344, 1). The larger OOP lattice constant of the two unit cells promotes the occupation of the 3d₃ᵣ_{²}-_{z}_{²} orbital which is known to lead to AFM interactions (Tebano, et al., Phys. Rev. Lett., 2008, 100, 137401). Therefore, the emergence of interfacial AFM coupling is highly anticipated. While the direct measurement of antiferromagnetism in interfacial thin layers is extremely challenging, an alternative route was taken to address this point by studying the magnetization. Knowing that the bulk part of LSMO film is FM, the system could exhibit exchange interaction via the coupling between bulk FM and interfacial AFM, as seen in conventional multilayer magnetic heterostructures (Nogues and Schuller, J. Magn. Magn. Mater., 1999, 192, 203; Hellman, et al., Rev. Mod. Phys., 2017, 89, 25006).

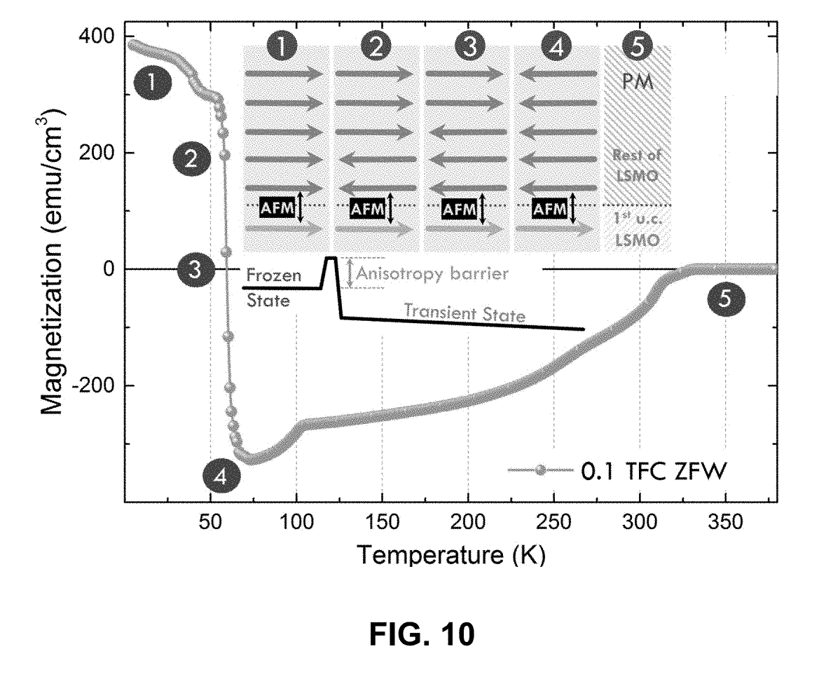

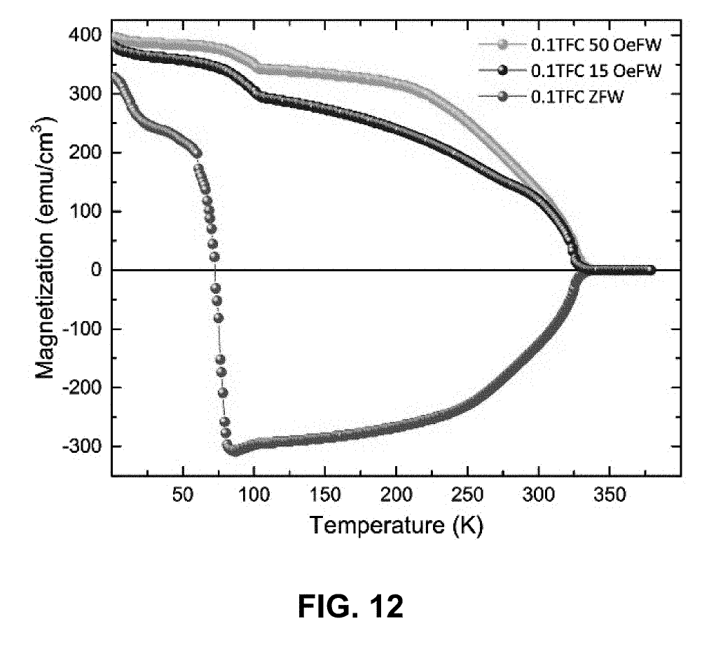

A careful measurement of magnetization was performed as a function of temperature using SQUID. Since LSMO is a soft FM, prior to magnetic measurement, the SQUID was demagnetized and calibrated using a standard palladium sample. The LSMO sample is first cooled from 380 K to 2 K in the presence of a 1000 Oe in-plane magnetic field. The magnetization as a function of temperature is measured during warming. In the absence of an external field during warming, i.e., zero field warming (ZFW), the remnant magnetic state is measured. FIG. 10 shows that at 2 K, the magnetization shows a positive moment in the same direction as the cooling field. Upon warming, the magnetic moment decreases slowly, then rapidly at 60 K, exhibiting a sharp and spontaneous magnetic reversal (SMR) (negative) at ˜75 K. Such reversal occurs in other film thicknesses as well (FIG. 11), indicating this is a thickness-independent property down to 10 unit cells. It is noteworthy that different types of field training resulted in different magnetization behavior as a function of temperature. The observed SMR disappears when a moderate magnetic field is applied during warming. In the presence of magnetic fields of 50 Oe and 15 Oe, no SMR was observed; instead, the M vs T curves exhibit normal ferromagnetic behavior (FIG. 12). To ensure that this result was not an artifact of the measurement, the time reversal configuration was examined, i.e. the direction of field cooling was reversed, and the result was the same but in the opposite direction. To further check the validity of the results, the same measurements were performed in a different SQUID, producing the same results.

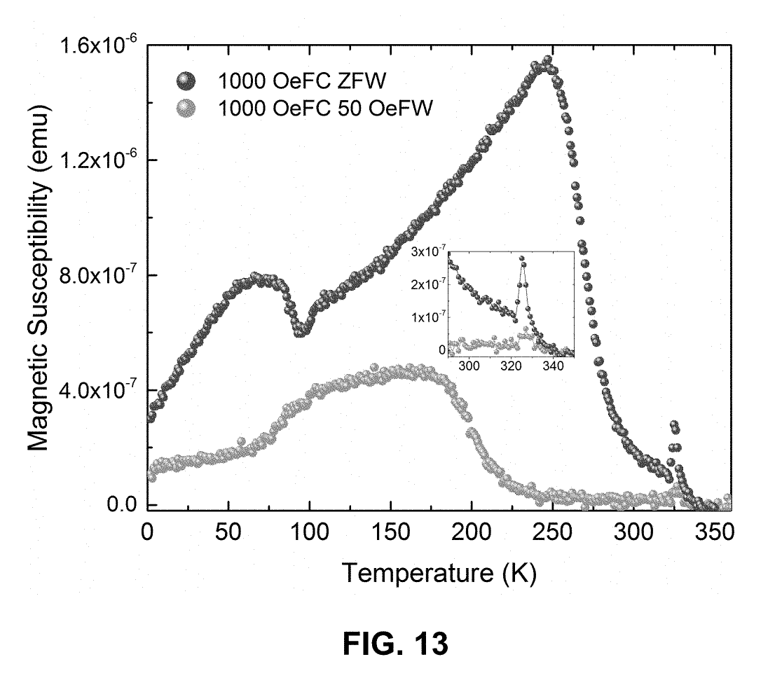

Coupling between FM and AFM layers has been shown to trigger SMR in other heterostructures (Li, et al., Phys Rev Lett, 2006, 96, 137201). SMR has been previously reported in LSMO (Lee, et al., Phys. Rev. Lett., 2010, 105, 257204), measured by X-ray magnetic circular dichroism (XMCD). However, the microscopic origin of this phenomenon remained unclear. The results presented herein indicate a structure and stoichiometry variation of LSMO near the interface and a full magnetic moment reversal from 60 to 75 K (FIG. 10), which together suggest that the SMR is triggered by the AFM interaction between the first unit cell at the interface and the rest of thin film. Specifically, in this system, there are two competing magnetic interactions: the AFM coupling energy between the first unit cell and rest of LSMO film and the Zeeman energy during the field cooling (Li, et al., Phys Rev Lett, 2006, 96, 137201). During field cooling, the two regions are forced to align in the direction of the external magnetic field. This magnetic configuration is frozen at 2 K (FIG. 10, inset). As the temperature increases under zero magnetic field, the AFM coupling, with the aid of thermal activation energy, begins to overcome the anisotropy barrier at around 70 K, which results in the SMR. This result is further supported by reentrant peak at ˜70 K in AC magnetic susceptibility (FIG. 13). Note that the cubic-to-tetragonal structural phase transition of STO at 105 K is apparent in the small kink at 105 K in FIG. 10. The SMR temperature precedes the STO transition temperature, therefore the antiferro-distortive transition of STO is likely not the reason for the SMR. These results suggest that the interface driven AFM interaction controls the magnetization of the entire thin film, including regions beyond the proximity of the interface. The spontaneous magnetic reversal (SMR) occurs in all LSMO/STO (001) thicknesses, as shown in FIG. 11. The kink due to the STO structural phase transition is indicated by an arrow. FIG. 12 shows the M vs T under different magnetic field cooling and warming. A magnetic field as small as 15 Oe can hinder the SMR.

FIG. 13 shows the AC magnetic susceptibility (real part) which is measured in 10 Hz. Magnetic susceptibility is a response function. Susceptibility shows a strong dependence on the applied magnetic field. Under no magnetic field, there are several magnetic features that vanish under a small magnetic field (50 Oe). The most obvious difference is centered at 60 K, which is the temperature that sees the onset of spontaneous magnetic reversal. In the presence of an external field, this feature completely diminishes, which explains the absence of spontaneous magnetic reversal under a magnetic field.

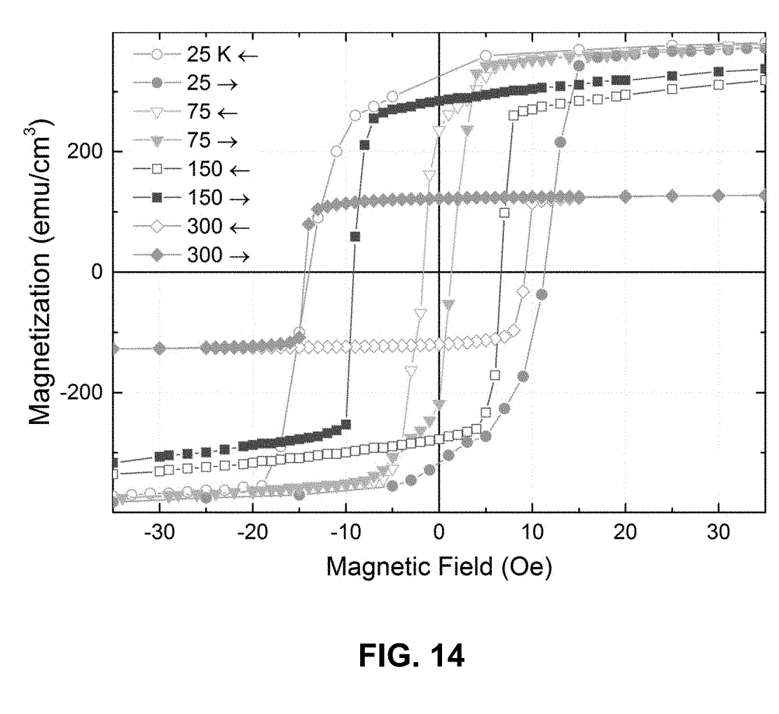

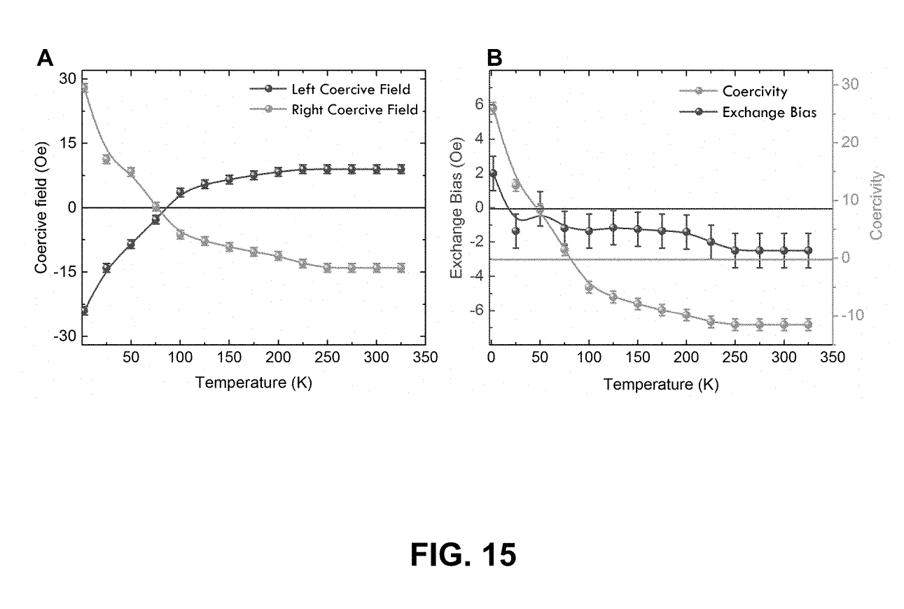

The magnetic hysteresis loops at different temperatures were measured and are shown in FIG. 14. Prior to each measurement, the thin film was cooled from 380 K to 2 K under a 1000 Oe magnetic field and then warmed up to temperature T under zero field, replicating the measurement procedure in FIG. 10. Each hysteresis cycle is presented in two half-cycles; empty symbols show the leftward half and solid symbols show the rightward half of hysteresis cycle. The hysteresis loop at 25 K represents the normal hysteresis for a soft FM with coercivity of 11 Oe, which agree with previous reports (Guo, et al., Adv. Mater. Interfaces, 2016, 3, 1500753; Boschker, et al., J. Phys. D. Appl. Phys., 2011, 44, 205001; Tsui, et al., Appl. Phys. Lett., 2000, 76, 2421). At 75 K, the left and right coercive fields start to move toward zero and hysteresis inversion starts to appear. Further temperature increase, past the reversal point, leads to an unusual hysteresis inversion. The magnetization reverses to a negative (positive) value in the presence of a positive (negative) magnetic field, hence the coercivity becomes negative. From 100 K to 275 K, the negative coercivity increases with increasing temperature and saturates at higher temperatures (FIG. 15 Element A). Negative coercivity persists up to 325 K, well above room temperature. This behavior may persist up to the Curie temperature. A close look at the hysteresis curves reveals a small exchange bias feature which characteristic of FM/AFM magnetic systems (FIG. 15 Element B). SMR and inverted hysteresis (IH) are both rare phenomena, where separately they have been reported in heterogeneous magnetic structures (Li, et al., Phys Rev Lett, 2006, 96, 137201; Ziese, et al., Appl. Phys. Lett., 2010, 97, 52504; Takanashi, et al., Appl. Phys. Lett., 1993, 63, 1585). In each case, only one of SMR or IH appears, and, because they appear due to interfacial AFM coupling, two magnetic materials are required. One material acts as a pinning layer and the other provides the magnetization, which is normally a combination of FM/AFM heterostructure. In the present work, SMR is the precursor of IH, where both occur in a monolithic thin film, and therefore the deposition of two magnetic materials is not required. Instead, presence of a near-interface layer serves as a pseudo-pinning layer, which triggers both SMR and IH. This approach greatly reduces the thickness and growth complexity in magnetism-based heterojunctions.

The results presented herein demonstrate an ability to realize momentary magnetic switching in a monolithic film. The observed SMR and IH show three features that are crucial for device applications: above room temperature functionality, reduced thin film dimensionality due to the interfacial region, and ease of fabrication due to one-step growth process. The AFM coupling between the interfacial region and the rest of the thin film functions as a switching device. FIG. 3 shows that a switching behavior is achievable. In the absence of magnetic field, the thin film bulk phase naturally aligns anti-parallel with the interfacial region, which exhibits a negative magnetization. By applying an external magnetic field in the positive direction, with a Zeeman energy larger than the AFM exchange coupling energy, the bulk magnetization of the thin film will align parallel with the external magnetic field and the pseudo-pinning layer. Upon removal of the external magnetic field, the AFM coupling favors an anti-parallel alignment again, acting as an exchange spring, and the magnetization points to the negative direction. The two switchable magnetic states are controlled by presence/absence of external magnetic field, which can be as small as 10 Oe. Previous studies have shown that the interface can modify the physical properties of the thin film through strain engineering, i.e. the unit cell dimensions of the substrate and thin film (Choi, et al., Science, 2004, 306, 1005), however, here the interface plays a more subtle role. The structural dimension, symmetry and octahedral tilt mismatch, as well as stoichiometric mismatch, i.e. broken symmetry at interface, which leads to a new AFM interaction that elevates the role of the interface from modifying to manipulating and controlling physical properties of the entire thin film. By selecting materials that have different symmetries, it may be possible to exploit the emerging interaction at the interface, which in turn results in new functionality.

In summary, these results demonstrate the ability to create emergent magnetic properties in a monolithic thin film. The structural and stoichiometric mismatch results in subtle structural and chemical modification across the interface, which changes the exchange interaction near the interface. Consequently, an AFM interaction is stabilized near the interface, which spontaneously reverses the magnetization and creates an inverted hysteresis that persists well above room temperature. Our results show that oxide interfaces with symmetry mismatch can lead to new magnetic interactions and functionalities, demonstrating an effective pathway toward fabrication of new functional devices, especially magnetic switching devices.

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention. The appended claims are intended to be construed to include all such embodiments and equivalent variations.

1. A magnetic thin film, comprising:
a single, magnetic layer of formula La₍ᵢ₋ₓ₎SrₓMnO₃ disposed over a non-magnetic substrate, the single magnetic layer having a bulk phase and an interfacial region that interfaces with the substrate;
wherein x is between 0 and 1; and
wherein the value of x is larger in the interfacial region than in the bulk phase.

2. The magnetic thin film of claim 1, wherein the value of x in the bulk phase is between 0.2 and 0.4.

3. The magnetic thin film of claim 1, wherein the value of x in the interfacial region is between 0.4 and 0.6.

4. The magnetic thin film of claim 1, wherein the thickness of the single magnetic layer is between 10 unit cells and 50 unit cells.

5. The magnetic thin film of claim 1, wherein the thickness of the interfacial region is about 2 unit cells.

6. The magnetic thin film of claim 1, wherein the Glaser notation tilt system in the interfacial region is a⁻a⁻c⁰.

7. The magnetic thin film of claim 1, wherein the oxygen octahedral tilt (OOT) of the thin film along [1-10]_{c} is lower in the interfacial region than in the bulk phase.

8. The magnetic thin film of claim 1, wherein the out-of-plane lattice constant of the interfacial region is about 3.923 Å.

9. The magnetic thin film of claim 1, wherein the substrate is strontium titanate.

10. The magnetic thin film of claim 1, wherein only the interfacial region in the single magnetic layer exhibits antiferromagnetic properties.

11. The magnetic thin film of claim 1, wherein the single magnetic layer exhibits both SMR and IH.

12. The magnetic thin film of claim 1, wherein the single magnetic layer exhibits SMR and IH below 340 K.

13. The magnetic thin film of claim 1, wherein the single magnetic layer exhibits SMR and IH at room temperature.

14. A magnetic data storage device comprising the magnetic thin film of claim 1.

15. A magnetic thin film, comprising:
a single layer of soft ferromagnetic material disposed over a non-magnetic substrate;
wherein the single layer of soft ferromagnetic material exhibits both SMR and IH below 340 K.

16. A method for the manufacture of transition metal oxide devices, the method comprising:
treating a surface of a non-magnetic substrate to create an atomically flat substrate surface;
placing the substrate in a growth chamber;
heating the substrate to a deposition temperature in the absence of oxygen;
introducing an oxygen/ozone mixture to the growth chamber; and
depositing a single transition metal oxide material onto the atomically flat substrate surface to form a single layer material having a bulk phase and an interfacial region that interfaces with the atomically flat substrate surface.

17. The method of claim 16, wherein the single transition metal oxide material is deposited using pulsed laser deposition.

18. The method of claim 16, wherein the deposition temperature is about 660° C.

19. The method of claim 17, wherein the single transition metal oxide material is deposited onto the atomically flat substrate surface less than about 1 minute after oxygen is introduced into the growth chamber.

20. The method of claim 17, wherein the pulsed laser deposition is performed using a laser frequency of about 10 Hz.
